(19) United States
(12) Patent Application Publication
(10) Pub. No.: US 2025/0043459 A1
(43) Pub. Date: Feb. 6, 2025

(54) MANUFACTURING METHOD OF SINGLE CRYSTAL AND SINGLE CRYSTAL MANUFACTURING DEVICE

(71) Applicant: SUMCO Corporation, Tokyo (JP)

(72) Inventors: Ippei SHIMOZAKI, Tokyo (JP); Keiichi TAKANASHI, Tokyo (JP); Ken HAMADA, Tokyo (JP); Taro NISHIDE, Tokyo (JP)

(73) Assignee: SUMCO Corporation, Tokyo (JP)

(21) Appl. No.: 18/687,096

(22) PCT Filed: Sep. 1, 2022
(86) PCT No.: PCT/JP2022/032979

§ 371 Date: Feb. 27, 2024

(30) Foreign Application Priority Data
Sep. 6, 2021 (JP) 2021-144871

(51) Int. Cl. C30B 15/26; C30B 15/14; C30B 29/06

(52) U.S. Cl. CPC C30B 15/26; C30B 15/14; C30B 29/06

(57) ABSTRACT

A manufacturing method of a single crystal includes providing a heat shield to cover an area above a crucible except for a pulling-up path of the single crystal; capturing with a first camera a real image of the heat shield and a mirror image of the heat shield reflected on a melt surface; setting a detection line extending in an oblique direction that is neither parallel nor perpendicular to a pulling-up axis of the single crystal and intersects both a real image edge and a mirror image edge of the heat shield; and finding a gap value, which is a distance between a lower end of the heat shield and the melt surface based on a distance on the detection line, between the real image and the mirror image.

### FIELD OF THE INVENTION

The present invention relates to a manufacturing method of a single crystal and a single crystal manufacturing device, particularly relating to a measuring method of a liquid surface level of melt during a single crystal pulling-up process by the Czochralski (CZ) method.

### BACKGROUND OF THE INVENTION

The CZ method is known as a manufacturing method of a silicon single crystal for a semiconductor device. In the CZ method, a polycrystalline silicon raw material in a quartz crucible is melted with heat, and by gradually pulling up a seed crystal immersed in the obtained silicon melt while relatively rotating the seed crystal, thereby growing a large single crystal at a lower end of the seed crystal. According to the CZ method, a high-quality silicon single crystal can be manufactured with a high yield.

In the CZ method, in order to improve the yield of single crystal and crystal quality, precise measurement and control for a crystal diameter and a liquid surface level are performed. For the measuring method of the crystal diameter and liquid surface level, for example, Patent Literature 1 describes a method of calculating a crystal diameter and a crystal center position from a high brightness portion called a fusion ring generated at a solid-liquid interface, and calculating the liquid surface level from the crystal center position. Also, Patent Literature 2 describes a method of calculating a liquid surface position of a silicon melt with respect to a heat shielding body from a space between a real image including a circular opening of the heat shielding body and a mirror image of the heat shielding body reflected on a melt surface. Patent Literature 3 describes a method of attaching a quartz rod above a melt surface and determining that the melt surface is in a standard position when a tip of the quartz rod contacts the melt surface. Patent Literature 4 describes a method of measuring a crystal diameter and calculating a height position of a silicon melt surface using a plurality of cameras.

In addition, Patent Literature 5 describes a method of suppressing evaporation of a dopant in a silicon melt by bringing the inside of a chamber under high pressure and also by placing a cylindrical furnace interior member, referred to as a purge tube, above a heat shielding body, and by rectifying purge gas introduced into a pulling-up furnace using the purge tube. Further, Patent Literature 6 describes a method of increasing a PvPi margin to improve a yield of defect-free crystal, by installing a cylindrical cooling body above a heat shielding body and controlling the residing time of a predetermined temperature range of a silicon single crystal pulled up from the silicon melt.

### RELATED ART

### Patent Literature

Patent Literature 1: Japanese Patent Laid-open Publication No. 2019-085299
Patent Literature 2: Japanese Patent Laid-open Publication No. 2013-216505
Patent Literature 3: Japanese Patent Laid-open Publication No. S62-087481
Patent Literature 4: Japanese Patent Laid-open Publication No. 2013-170097
Patent Literature 5: Japanese Patent Laid-open Publication No. 2011-246341
Patent Literature 6: Japanese Patent Laid-open Publication No. 2021-098629

### SUMMARY OF THE INVENTION

### Problems to be Solved by the Invention

Generally, one camera is used to capture an image inside a furnace, and a center in a width direction of a shooting range is set at a center of a single crystal so as to show the entire single crystal in a diameter direction. In other words, an optical axis of the camera is set in a plane that includes a crystal pulling-up axis. However, when a furnace interior structure such as the purge tube and a water cooling body is set above the heat shielding body and a view of the camera is blocked by the furnace interior structure, a real image and mirror image of the heat shielding body cannot be captured and a liquid surface level with respect to the heat shielding body cannot be measured.

Accordingly, the present invention intends to provide a manufacturing method of a single crystal and a single crystal manufacturing device that can stably measure the liquid surface level regardless of the furnace interior structure.

### Means for Solving the Problems

In order to resolve the above concerns, a manufacturing method of a single crystal according to the present invention is a manufacturing method of a single crystal by the Czochralski method that pulls up a single crystal from a melt in a crucible, and includes providing the heat shielding body to cover an area above the crucible except for a pulling-up path of the single crystal; capturing with a first camera a real image of the heat shielding body and a mirror image of the heat shielding body reflected on a melt surface; setting a detection line extending in an oblique direction that is neither parallel nor perpendicular to a pulling-up axis of the single crystal and intersects both a real image edge and a mirror image edge of the heat shielding body; and finding a gap value, which is a distance between a lower end of the heat shielding body and the melt surface based on a distance from a first intersection point of the detection line and the real image edge to a second intersection point of the detection line and the mirror image edge (real image-mirror image distance on the detection line).

According to the present invention, the real image and mirror image of the heat shielding body, which until now could not be captured from a shooting direction of a diameter-measuring camera by being hidden by the shield, can be captured. Therefore, it is possible to stably measure the liquid surface level regardless of the structure inside or outside of the furnace.

In the present invention, the optical axis of the first camera is preferably in a twisted positional relationship, not in the same plane as the pulling-up axis of the single crystal. In this way, by shifting the center in the width direction of the shooting range of the first camera from the center of the single crystal, the real image and the mirror image of the heat shielding body can be captured and setting the detection line becomes easier. In addition, the distance from the first intersection point of the detection line and the real image edge to the second intersection point of the detection line and the mirror image edge can be increased, and the gap value which is the distance between the lower end of the heat shielding body and the melt surface can be calculated more accurately.

In the present invention, it is preferable to measure the diameter of the single crystal using a second camera provided separately from the first camera, and the optical axis of the second camera is preferably in the same plane as the pulling-up axis and is in an intersecting positional relationship. In this way, by providing the first camera for measuring a gap separately from the second camera for measuring the diameter, the gap value which is the distance from the lower end of the heat shielding body and the melt surface can be stably measured.

In the present invention, it is preferable to set a substantially cylindrical shield surrounding the pulling-up path above the lower end of the heat shielding body, and the view of the second camera is blocked by the shield. When the furnace interior structure such as the purge tube is set above the crucible separately from the heat shielding body, the real image and mirror image of the heat shielding body cannot be observed from the diameter-measuring main camera. However, the gap value can be reliably measured by setting a camera in a position where the real image and mirror image of the heat shielding body can be observed without blocking the view by the shield and by capturing the real image and mirror image of the heat shielding body. In this case, since the center in the width direction of the shooting range of the camera is shifted from the center of the single crystal, the real image and mirror image of the heat shielding body can be observed from a small gap between the lower end of the shield and the heat shielding body.

In the present invention, it is preferable to prepare in advance a conversion table or a conversion formula indicating the relationship between the gap value and the real image-mirror image distance on the detection line when the liquid surface level of the melt is arbitrarily changed by lifting and lowering the crucible before starting to pull up the crystal, and calculate the gap value using the actually measured real image-mirror image distance and conversion table or conversion formula during a crystal pulling-up step. By doing so, the gap value can be calculated accurately.

In the present invention, it is preferable to obtain a standard liquid surface level by observing the contact between a measuring pin arranged above the melt and the melt surface, and to prepare the conversion table or the conversion formula based on the standard liquid surface level. By doing so, the gap value can be calculated accurately.

Also, a single crystal manufacturing device according to the present invention includes a crucible supporting the melt, a crucible driving mechanism that rotates and drives elevation of the crucible, a heater for heating the melt in the crucible, a cylindrical heat shielding body arranged in an area above the crucible except for a pulling-up path of the single crystal, a first camera that captures a real image of the heat shielding body and a mirror image of the heat shielding body reflected on the liquid surface of the melt, an image processor that processes the image captured by the first camera to obtain the gap value between the lower end of the heat shielding body and the melt surface, and a controller that controls the liquid surface level of the melt based on the processing results of the captured image by the image processor. The image processor, while capturing the image, sets a detection line extending in an oblique direction that is neither parallel nor perpendicular to a pulling-up axis of the single crystal and intersects both a real image edge and a mirror image edge of the heat shielding body and finds a gap value, which is a distance between a lower end of the heat shielding body and the melt surface based on a distance from a first intersection point of the detection line and the real image edge to a second intersection point of the detection line and the mirror image edge (real image-mirror image distance on the detection line).

In the present invention, an optical axis of the first camera is preferably in a twisted positional relationship, not in the same plane as the pulling-up axis of the single crystal. In this way, by shifting the center in the width direction of the shooting range of the first camera from the center of the single crystal, the real image and the mirror image of the heat shielding body can be captured and setting the detection line becomes easier. In addition, the distance from the first intersection point of the detection line and the real image edge to the second intersection point of the detection line and the mirror image edge can be increased, and the gap value which is the distance between the lower end of the heat shielding body and the melt surface can be calculated more accurately.

In the present invention, it is preferable to further includes a second camera that captures the real image of the heat shielding body and the mirror image of the heat shielding body reflected on the liquid surface of the melt, and the image processor measures the diameter of the single crystal using the second camera.

In the present invention, the image processor preferably prepares in advance a conversion table or a conversion formula indicating a relationship between the gap value and the real image-mirror image distance on the detection line when the liquid surface level of the melt is arbitrarily changed by lifting and lowering the crucible before starting pulling up the crystal, and calculates the gap value using the actually measured real image-mirror image distance and conversion table or conversion formula during the crystal pulling-up step.

The present invention preferably further includes a measuring pin arranged above the melt, and the image processor preferably obtains a standard liquid surface level by observing the contact between a tip of the measuring pin and the melt surface, and prepares the conversion table or the conversion formula based on the standard liquid surface level.

### Effect of the Invention

The present invention provides a manufacturing method of a single crystal and a single crystal manufacturing device that can stably measure the liquid surface level regardless of the furnace interior structure.

### BRIEF DESCRIPTION OF THE DRAWINGS

FIG. 1 is a side sectional view schematically illustrating a configuration of a single crystal manufacturing device according to an embodiment of the present invention.

FIG. 2 is a schematic view describing positions where two cameras are arranged.

FIG. 3 is a schematic view of an image 30A captured by a main camera 20A (diameter-measuring camera); (a) is a view not illustrating an outline of a single crystal, and (b) is a view illustrating the outline of the single crystal by an auxiliary line.

FIG. 4 is a schematic view illustrating an image captured by a gap-measuring sub camera.

FIG. 5 is a schematic view illustrating a measuring method of a standard liquid surface level using a measuring pin.

FIG. 6 is a flow chart illustrating a manufacturing process of a silicon single crystal.

### MODE FOR CARRYING OUT THE INVENTION

Hereafter, a preferred embodiment of the present invention is described in detail with reference to the attached drawings.

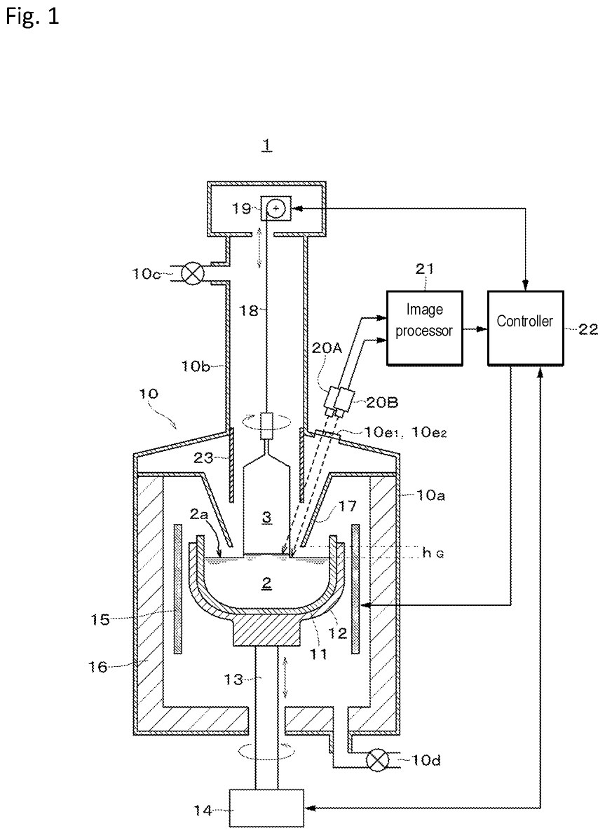

FIG. 1 is a side sectional view schematically illustrating a configuration of a single crystal manufacturing device according to an embodiment of the present invention.

As illustrated in FIG. 1, a single crystal manufacturing device 1 includes a water cooling chamber 10, a quartz crucible 11 that holds silicon melt 2 in the chamber 10, a graphite crucible 12 that holds the quartz crucible 11, a rotating shaft 13 supporting the graphite crucible 12, a crucible driving mechanism 14 that rotates and drives elevation of the quartz crucible 11 via the rotating shaft 13 and the graphite crucible 12, a heater 15 that is arranged around the circumference of the graphite crucible 12, thermal insulation material 16 that is arranged outside of the heater 15 and along an inner surface of the chamber 10, a heat shielding body 17 that is arranged above the quartz crucible 11, a pulling wire 18 that is above the quartz crucible 11 and positioned coaxially with the rotating shaft 13, a crystal pulling-up mechanism 19 that is arranged above the chamber 10, two cameras 20A and 20B that captures images inside the chamber 10, an image processor 21 that processes images captured by the cameras 20A and 20B, and a controller 22 that controls various components in the single crystal manufacturing device 1.

The chamber 10 is configured with a main chamber 10a and a slender cylindrical pull chamber 10b which is connected to an upper opening of the main chamber 10a, and the quartz crucible 11, graphite crucible 12, heater 15, and heat shielding body 17 are provided inside the main chamber 10a. The pull chamber 10b is provided with a gas inlet 10c for introducing dopant gas or inert gas (purge gas) such as argon gas into the chamber 10, and a gas outlet 10d is provided at the bottom of the main chamber 10a to discharge atmosphere gas in the chamber 10. In addition, a first observation window 10e₁ and a second observation window 10e₂ are provided at an upper portion of the main chamber 10a and growth status of a silicon single crystal 3 can be observed.

The quartz crucible 11 is a container that is made of quartz glass having a cylindrical side wall and a curved bottom. The graphite crucible 12 is adhered to an external surface of the quartz crucible 11 and is held so as to wrap around the quartz crucible 11 in order to maintain the shape of the quartz crucible 11 which softens by heating. The quartz crucible 11 and the graphite crucible 12 configure a double structure crucible that supports the silicon melt 2 in the chamber 10.

The graphite crucible 12 is fixed to the upper end portion of the rotating shaft 13, and the lower end portion of the rotating shaft 13 passes through the bottom of the chamber 10 to connect to the crucible driving mechanism 14 that is provided outside the chamber 10. The graphite crucible 12, the rotating shaft 13, and the crucible driving mechanism 14 configure a rotation mechanism and an elevation mechanism of the quartz crucible 11. The operations of rotating and elevating the quartz crucible 11 driven by the crucible driving mechanism 14 are controlled by the controller 22.

The heater 15 is used to melt silicon raw material filled inside the quartz crucible 11 to generate the silicon melt 2, as well as to maintain a molten state of the silicon melt 2. The heater 15 is a resistance thermal heater made of carbon and is provided surrounding the quartz crucible 11 inside the graphite crucible 12. Further, the thermal insulation material 16 is provided outside the heater 15 to surround the heater 15, thereby enhancing heat retention inside the chamber 10. Output of the heater 15 is controlled by the controller 22.

The heat shielding body 17 is provided to suppress temperature fluctuation in the silicon melt 2 to provide appropriate heat distribution near a crystal growth interface, and also to prevent heating of the silicon single crystal 3 by radiation heat from the heater 15 and the quartz crucible 11. The heat shielding body 17 is a substantially cylindrical member made of graphite, and is provided to cover the area above the silicon melt 2 except for a pulling-up path of the silicon single crystal 3.

A diameter of the opening on the lower end of the heat shielding body 17 is larger than the diameter of the silicon single crystal 3, thereby ensuring the pulling-up path of the silicon single crystal 3. In addition, an outer diameter of the lower end portion of the heat shielding body 17 is smaller than an aperture of the quartz crucible 11 and the lower end portion of the heat shielding body 17 is located inside the quartz crucible 11, and therefore, the heat shielding body 17 does not interfere with the quartz crucible 11 even when an upper end of a rim of the quartz crucible 11 is raised to above the lower end of the heat shielding body 17.

Although the amount of melt in the quartz crucible 11 decreases as the silicon single crystal 3 grows, the quartz crucible 11 is raised so that the space (gap value h_{G}) between a melt surface and the heat shielding body 17 is constant, thereby controlling the temperature fluctuation of the silicon melt 2 and controlling evaporation of dopant from the silicon melt 2 by keeping constant the flow speed of gas flowing in the vicinity of the melt surface. Such gap control allows improvement of the stability of crystal defect distribution, oxygen concentration distribution, resistivity distribution, and the like in a pulling-up axis direction of the silicon single crystal 3.

The wire 18 which is the pulling-up axis of the silicon single crystal 3, and the crystal pulling-up mechanism 19 that pulls the silicon single crystal 3 by winding the wire 18 are provided above the quartz crucible 11. The crystal pulling-up mechanism 19 has a function to rotate the wire 18 and the silicon single crystal 3. The crystal pulling-up mechanism 19 is controlled by the controller 22. The crystal pulling-up mechanism 19 is arranged above the pull chamber 10b, and the wire 18 is extended downward from the crystal pulling-up mechanism 19 through the pull chamber 10b, and the distal end of the wire 18 reaches the inner space of the main chamber 10a. FIG. 1 shows a state where the silicon single crystal 3 in the middle of growth is suspended on the wire 18. When pulling the silicon single crystal 3, the silicon single crystal 3 is grown by pulling the wire 18 gradually while rotating each of the quartz crucible 11 and the silicon single crystal 3.

Two cameras 20A and 20B are arranged outside the chamber 10. The cameras 20A and 20B are a CCD camera, for example, and capture an image of the inside of the chamber 10 via the first and second observation window 10e₁ and 10e₂ which is formed in the chamber 10. The installation angle of the cameras 20A and 20B forms a predetermined angle to a vertical direction, and the cameras 20A and 20B have an optical axis tilted with respect to the pulling-up axis of the silicon single crystal 3. In other words, the cameras 20A and 20B capture image obliquely from above a top surface region of the quartz crucible 11 including the circular opening of the heat shielding body 17 and the melt surface of the silicon melt 2.

The cameras 20A and 20B are connected to the image processor 21 and the image processor 21 is connected to the controller 22. The image processor 21 calculates a crystal diameter in the vicinity of a solid-liquid interface from an outline pattern of the single crystal shown in the image captured by the camera 20A. In addition, the image processor 21 calculates the distance (gap value h_{G}) between the heat shielding body 17 and the liquid surface position from the position of the mirror image of the heat shielding body 17 that is reflected on the melt surface in the image captured by the cameras 20A and 20B. In order to eliminate noise effect, it is preferred to use the average value of the multiple values as a gap-measuring value which is used for the actual gap control.

The method of calculating the gap value h_{G} from the position of the mirror image of the heat shielding body 17 is not particularly limited, but for example, a conversion table or a conversion formula indicating the relationship between the gap and the position of the mirror image of the heat shielding body 17 is prepared in advance, and the gap can be found by substituting the position of the mirror image of the heat shielding body 17 into the conversion table or conversion formula during the crystal pulling-up process. Further, the gap can be geometrically calculated from the positional relationship between the real image and the mirror image of the heat shielding body 17 shown in the captured image.

The controller 22 controls the crystal diameter by controlling a crystal pulling-up speed based on the crystal diameter data obtained from the image captured by the camera 20A. Specifically, when a measured value of the crystal diameter is greater than a target diameter, the crystal pulling-up speed is increased, and when the measured value of the crystal diameter is smaller than the target diameter, the pulling-up speed is decreased. In addition, the controller 22 controls a movement amount (crucible lifting speed) of the quartz crucible 11 so as to be a predetermined gap value based on the crystal length data of the silicon single crystal 3 that is obtained from a sensor of the crystal pulling-up mechanism 19 and the gap value (liquid surface level) obtained from the image captured by at least one of the cameras 20A and 20B. At this point, in addition to a case where the gap value is controlled to be maintained at a constant value, there is a case where the gap value is controlled to gradually decrease or conversely increase as the single crystal pulling-up progresses.

A cylindrical shield 23 surrounding the crystal pulling-up axis is provided above the heat shielding body 17. The shield 23 may be a structure called a purge tube or a cooling body that promotes cooling of the silicon single crystal 3 which is pulled up.

The purge tube is provided to control the flow of purge gas. In order to adjust resistivity of the silicon single crystal to match characteristics of a semiconductor device, impurities (dopant) such as arsenic (As) and antimony (Sb) may be doped into the silicon melt. These dopants have low boiling point and evaporate easily. In a general crystal pulling-up by the CZ method, since the purge gas such as Ar gas is flowing into the pulling-up furnace under reduced pressure, the dopant evaporated from the silicon melt 2 volatilizes on the purge gas and contaminates inside of the furnace. In addition, the heat shielding body 17 provided inside the furnace accelerates the flow speed of the purge gas that flows near the surface of the silicon melt 2 and evaporation of the dopant from the silicon melt 2 is further promoted. However, when the purge tube is provided, it is possible to suppress evaporation of the dopant in the silicon melt by bringing the inside of the chamber under high pressure as well as placing the purge tube above the heat shielding body 17, thereby rectifying the purge gas introduced into the pulling-up furnace.

The cooling body is provided to control time of the silicon single crystal, which has been pulled up from the silicon melt 2, to pass through a predetermined temperature range. The type and distribution of crystal defect included in the silicon single crystal manufactured by the CZ method is known to depend on the ratio V/G between the silicon single crystal growth rate V (pulling-up speed) and temperature gradient G inside the crystal in the pulling-up axis direction near the crystal growth interface from the melting point to 1300° C. By strictly controlling V/G, the single crystal free of crystal originated particle (COP) or dislocation clusters can be manufactured. Here, as the crystal diameter is larger, the center of the crystal becomes harder to cool compared to an outer periphery of the crystal, and the temperature gradient G in a cross-section of the silicon single crystal orthogonal to the pulling-up axis direction tends to become non-uniform. Accordingly, the allowable range of V/G that allows the entire surface in the cross-section of the silicon single crystal orthogonal to the pulling-up axis direction to be a zero defect region becomes very narrow, and controlling the crystal pulling-up speed V suddenly becomes difficult. However, when the cylindrical cooling body is installed above the heat shielding body 17, the allowable range (PvPi margin) of the crystal pulling-up speed V that allows the entire surface in the cross-section of the silicon single crystal orthogonal to the pulling-up axis direction to be a zero defect region can be enlarged and, a manufacturing yield of large-diameter silicon single crystal that is free of COP and dislocation clusters can be increased.

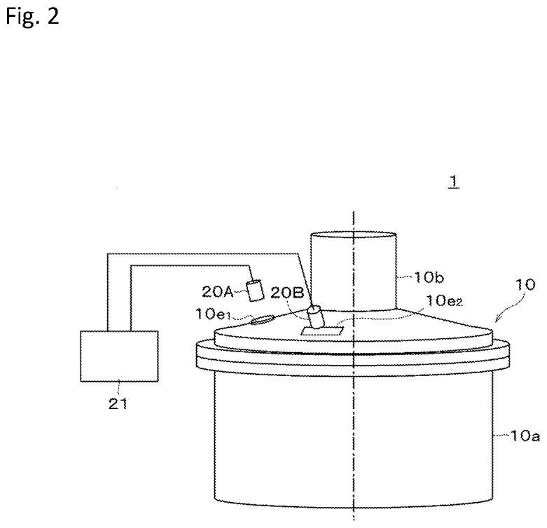

FIG. 2 is a schematic view describing positions where two cameras 20A and 20B are arranged.

As shown in FIG. 2, the single crystal manufacturing device 1 according to the present embodiment includes a gap-measuring sub camera 20B (first camera) provided separately from the diameter-measuring main camera 20A (second camera). The diameter-measuring main camera 20A is provided directly opposite the silicon single crystal, and the optical axis of the main camera 20A is in the same plane as the crystal pulling-up axis and is in the intersecting positional relationship with the crystal pulling-up axis. Meanwhile, the sub camera 20B captures image of the silicon single crystal from an oblique direction and the optical axis of the sub camera 20B is arranged in the oblique direction that is neither parallel nor perpendicular to the crystal pulling-up axis and is in the twisted positional relationship with the crystal pulling-up axis. Therefore, even when the view of the main camera 20A is blocked by the shield 23, the mirror image edge of the heat shielding body 17 reflected on the melt surface can be observed from a small gap between the lower end of the shield 23 and the heat shielding body 17.

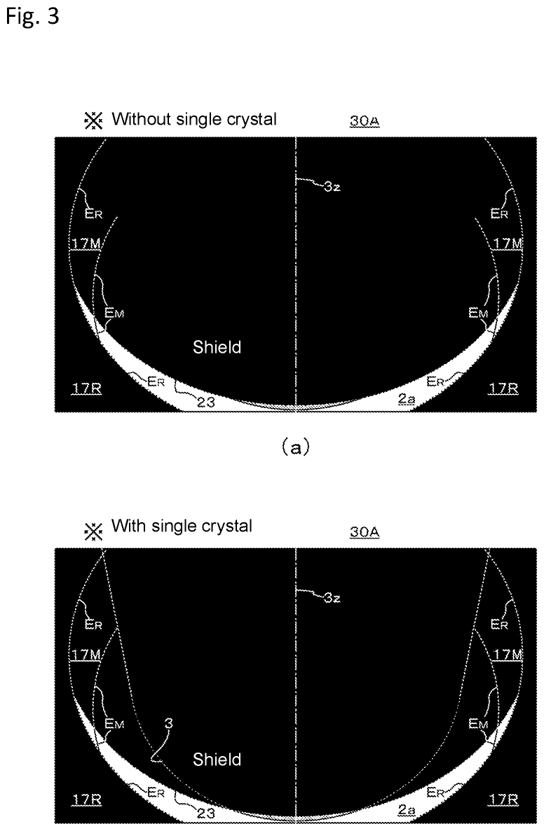

FIG. 3 is a schematic view of an image 30A captured by the main camera 20A (diameter-measuring camera); (a) is a view not illustrating an outline of the single crystal, and (b) is a view illustrating the outline of the single crystal by an auxiliary line.

As shown in FIGS. 3(a) and (b), the main camera 20A captures image of the silicon single crystal 3 obliquely from above. In particular, the optical axis of the main camera 20A is set in a plane that includes the crystal pulling-up axis (crystal center axis 3z) and the center in the width direction of the shooting range is set to align with the center of the single crystal so as to show entirely in the diameter direction thereof. The dotted lines and chain lines in the drawings are auxiliary lines for explanation and do not exist in the actual captured image.

When the shield 23 such as the purge tube and the water cooling body is not set above the heat shielding body 17, the main camera 20A can capture image of a real image 17R and a mirror image 17M of the heat shielding body 17. In the captured image 30A, the heat shielding body 17 and shield 23 appear dark, but the melt surface 2a appears bright due to radiant light or reflected light. However, as illustrated in the drawing, when the shield 23 is set above the heat shielding body 17, the view of the main camera 20A is blocked by the shield 23, and therefore the real image 17R and mirror image 17M of the heat shielding body 17 cannot be captured. As illustrated in the drawing, the shield 23 in the captured image 30A appears dark similar to the heat shielding body 17 and the like, and therefore, the majority of the captured image is completely dark and the only area that appears bright is only a small portion of the melt surface 2a and the single crystal in the vicinity of the solid-liquid interface that can be seen through a small gap between the shield 23 and the real image 17R of the heat shielding body 17. For ease of explanation, a portion of the real image edge E_{R} and the mirror image edge E_{M} of the heat shielding body 17 is shown by the dashed lines, but they are not actually visible.

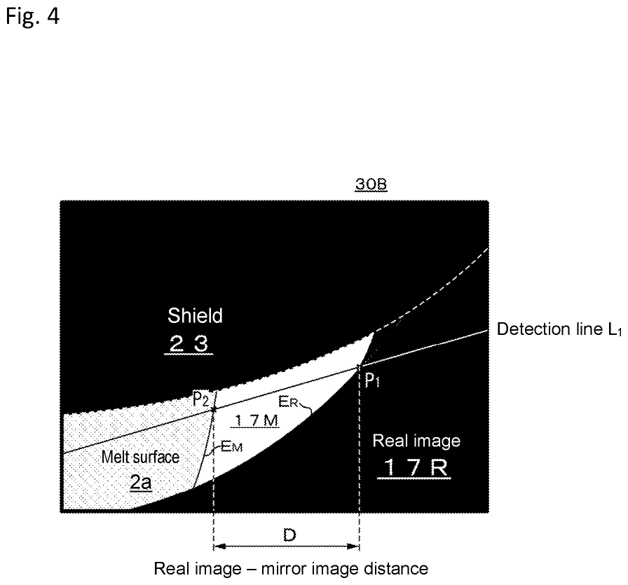

FIG. 4 is a schematic view illustrating an image 30B captured by the sub camera 20B (gap-measuring camera).

As shown in FIG. 4, the sub camera 20B also captures image of the silicon single crystal obliquely from above, but the center in the width direction of the shooting range is not aligned with the center of the silicon single crystal and the optical axis of the sub camera 20B is oriented to intersect the plane that includes the silicon crystal pulling-up axis. The sub camera 20B, as illustrated in the drawing, captures image locally in the vicinity of the solid-liquid interface on the right side (or the left side) away from the crystal pulling-up axis (crystal center axis 3z). Therefore, the mirror image of the heat shielding body 17 reflected on the melt surface 2a can be observed from a small gap between the lower end of the shield 23 and the heat shielding body 17.

When finding the gap value h_{G} from the image 30B captured by the sub camera 20B in this way, first, a detection line L₁ intersecting each of the real image edge E_{R} and the mirror image edge E_{M} of the heat shielding body 17 is set in the captured image 30B. Until now, the detection line L₁ was set in the horizontal direction orthogonal to the crystal pulling-up axis (crystal center axis 3z), but in the present embodiment, the detection line L₁ is set in an oblique direction. In particular, it is preferable to draw the detection line L₁ so that the distance (pixel count) between the two intersections is maximum, and the detection line L₁ is preferably drawn substantially parallel to the extension direction of the edge of the shield 23. By doing so, the distance between the two intersections is sufficiently ensured and the measuring accuracy of the gap value can be enhanced.

Next, the coordinates of an intersection point P₁ (first intersection point) between the detection line L₁ and the real image edge E_{R} and an intersection point P₂ (second intersection point) between the detection line L₁ and the mirror image edge E_{M} are calculated respectively, and the distance from the first intersection point P₁ to the second intersection point P₂ (the real image-mirror image distance D on the detection line L₁) is obtained, and the gap value h_{G} between the lower end of the heat shielding body 17 and the melt surface 2a is found from the real image-mirror image distance D. The dashed lines in the drawings are auxiliary lines for explanation and do not exist in the actual captured image 30B.

When calculating the gap value h_{G} from the real image-mirror image distance D, the conversion table or conversion formula that are prepared in advance before starting the crystal pulling-up step can be used for the calculation. The conversion table or conversion formula can be obtained from the relationship between the real image-mirror image distance D on the detection line L₁ and the relative change of the gap value h_{G} when the liquid surface level of the silicon melt 2 is arbitrarily changed by lifting and lowering the quartz crucible 11. Further, a reference value (absolute value) of the gap value h_{G} can be found by a measuring method of a standard liquid surface level using a quartz measuring pin (quartz rod), for example.

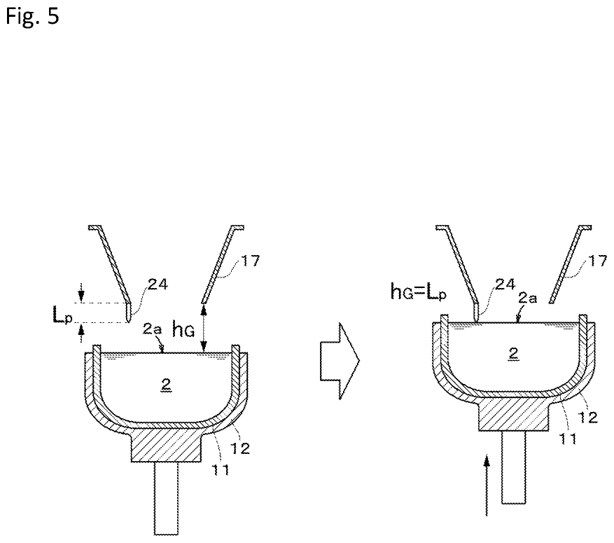

FIG. 5 is a schematic view illustrating a measuring method of a standard liquid surface level using a measuring pin.

As shown in FIG. 5, in measuring the standard liquid surface level using the measuring pin, a measuring pin 24 with a predetermined length Lp is attached to the lower end of the heat shielding body 17 covering above the melt surface 2a, and the state of contact between the tip of the measuring pin 24 and the melt surface 2a is observed while gradually raising the quartz crucible 11 together with the melt surface 2a. Also, when the tip of the measuring pen 24 contacts the melt surface 2a, it is determined that the melt surface has reached the standard liquid surface level. In other words, when the measuring pin 24 contacts the melt surface 2a, it is determined that the gap value he has matched the length Lp (Lp=h_{G}) of the measuring pin 24. This method can be referred to as a true value of the gap value h_{G} because of high measurement accuracy of the liquid surface level.

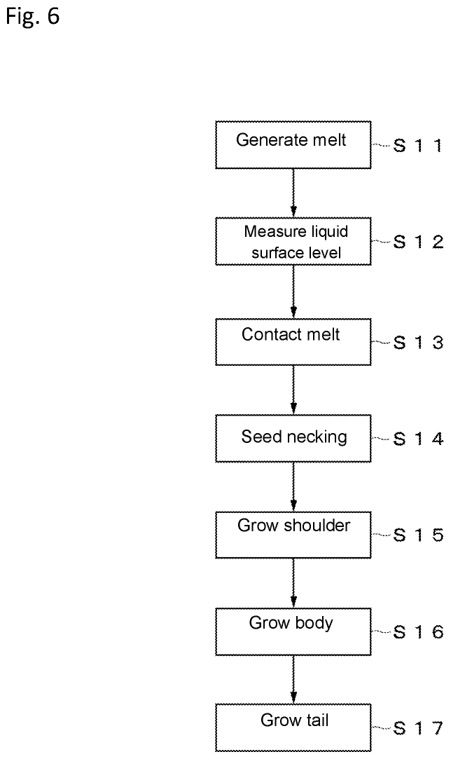

FIG. 6 is a flow chart illustrating a manufacturing process of the silicon single crystal.

As shown in FIG. 6, in manufacturing the silicon single crystal 3, a polycrystalline silicon raw material filled inside the quartz crucible 11 in advance is heated with the heater 15 to generate the silicon melt 2 (step S11). Next, the liquid surface position of the silicon melt 2 (gap value h_{G}) observed from the heat shielding body 17 is measured (step S12). Then, the seed crystal that is attached to a distal end of the wire 18 is lowered to be brought into contact with the silicon melt 2 (step S13). A descending amount of the seed crystal at this time is determined based on the gap value h_{G} that has been measured in advance.

Next, the crystal pulling-up process that grows the silicon single crystal 3 by gradually pulling up the seed crystal while maintaining the state of contact with the silicon melt 2 is initiated. In the crystal pulling-up process, first, seed necking (step S14) is performed by a dash necking method to achieve a dislocation-free single crystal. Next, in order to obtain the single crystal with required diameter, a shoulder where the diameter gradually increases is grown (step S15), and when the single crystal reaches the desired diameter, a body maintaining a constant diameter is grown (step S16). After the body grows to the predetermined length, tail necking (growing tail, step S17) is performed to separate the single crystal from the silicon melt 2 in a dislocation-free state.

During the crystal pulling-up process, the diameter of the silicon single crystal 3 and the liquid surface position of the silicon melt 2 are controlled. The controller 22 controls pulling-up conditions such as pulling-up speed of the wire 18 and power of the heater 15 so that the diameter of the silicon single crystal 3 becomes the target diameter. Also, the controller 22 controls the position of the quartz crucible 11 in the vertical direction so that the gap value h_{G} corresponding to the liquid surface position becomes a predetermined value.

As described above, the manufacturing method of the silicon single crystal according to the present embodiment includes the gap-measuring sub camera 20B provided separately from the diameter-measuring main camera 20A and the real image and mirror image of the heat shielding body 17 are captured by the sub camera 20B. Therefore, even when the view of the main camera 20A is blocked by the shield 23 such as the purge tube, the real image and mirror image of the heat shielding body 17 can be captured and the gap value h_{G} can be stably measured. In addition, when finding the gap value h_{G} from the image captured by the sub camera 20B, the detection line L₁ is drawn in the oblique direction instead of the horizontal direction, and the gap value h_{G} is calculated from the intersection points P₁ and P₂ of this detection line L₁ and the real image edge E_{R} and the mirror image edge E_{M} respectively, and therefore, the measuring accuracy of the gap value h_{G} can be enhanced.

The present invention is not limited to the embodiment above. Various modifications can be added without departing from the scope of the present invention, and such modifications are, of course, covered by the scope of the present invention.

For example, in the embodiment described above, a case where the view of the diameter-measuring camera is blocked by the shield is given as an example, however the present invention is not limited to such a case, and the gap can be measured using the gap-measuring camera separately from the diameter-measuring camera even when there is no shield blocking the view of the diameter-measuring camera. Accordingly, gap measurement accuracy and reliability can be improved. In addition, it is possible to provide a gap-measuring camera alone without a diameter-measuring camera. Further, the present invention is not limited to a case where the gap-measuring camera is used together with the diameter-measuring camera, but the gap-measuring camera can also be used alone.

Further, in the embodiment described above, a manufacturing method of a silicon single crystal is described, however the present invention can be applied to a manufacturing method of various single crystals for which the CZ method can be utilized.

### DESCRIPTION OF REFERENCE NUMERALS

1 Single crystal manufacturing device
2 Silicon melt
2a Melt surface
3 Silicon single crystal
3z Crystal center axis (Crystal pulling-up axis)
10 Chamber
10a Main chamber
10b Pull chamber
10c Gas inlet
10d Gas outlet
10e₁ First observation window
10e₂ Second observation window
11 Quartz crucible
12 Graphite crucible
13 Rotating shaft
14 Crucible driving mechanism
15 Heater
16 Thermal insulation material
17 Heat shielding body
17M Mirror image of heat shielding body
17R Real image of heat shielding body
18 Wire
19 Crystal pulling-up mechanism
20A Main camera (Diameter-measuring camera)
20B Sub camera (Gap-measuring camera)
21 Image processor
22 Controller
23 Shield (Furnace interior structure)
24 Measuring pin
30A Image captured by main camera
30B Image captured by sub camera
E_{M} Mirror image edge of heat shielding body
E_{R} Real image edge of heat shielding body
L₁ Detection line
P₁ Intersection point of detection line and real image edge (First intersection point)
P₂ Intersection point of detection line and mirror image edge (Second intersection point)

1. A manufacturing method of a single crystal by the Czochralski method that pulls up a single crystal from a melt in a crucible, comprising:
providing a heat shielding body that covers an area above the crucible except for a pulling-up path of the single crystal;
capturing a real image of the heat shielding body and a mirror image of the heat shielding body reflected on a melt surface of the melt by a first camera;
setting a detection line extending in an oblique direction that is neither parallel nor perpendicular to a pulling-up axis of the single crystal and intersects both a real image edge and a mirror image edge of the heat shielding body; and
finding a gap value, which is a distance between a lower end of the heat shielding body and the melt surface based on a distance on the detection line between the real image and the mirror image, which is a distance from a first intersection point of the detection line and the real image edge to a second intersection point of the detection line and the mirror image.

2. The manufacturing method of the single crystal according to claim 1, wherein an optical axis of the first camera is in a twisted positional relationship, not in the same plane as a pulling-up axis of the single crystal.

3. The manufacturing method of the single crystal according to claim 1, wherein a diameter of the single crystal is measured using an image captured by a second camera provided separately from the first camera.

4. The manufacturing method of the single crystal according to claim 1, wherein a conversion table or a conversion formula is prepared in advance, that indicates a relationship between distance on the detection line between the real image and the mirror image and the gap value when a liquid surface level of the melt is arbitrarily changed by lifting and lowering the crucible before starting to pull up the crystal, and calculates the gap value using the actually measured distance between the real image and the mirror image, and conversion table or conversion formula during a step of pulling-up of the crystal.

5. The manufacturing method of the single crystal according to claim 4, wherein a standard liquid surface level is obtained by observing a contact between a measuring pin arranged above the melt and the melt surface, and prepares the conversion table or the conversion formula based on the standard liquid surface level.

6. A single crystal manufacturing device comprising:
a crucible supporting a melt;
a crucible driving mechanism that rotates and drives elevation of the crucible;
a heater for heating the melt in the crucible;
a cylindrical heat shielding body arranged in an area above the crucible except for a pulling-up path of the single crystal;
a first camera that captures a real image of the heat shielding body and a mirror image of the heat shielding body reflected on a liquid surface of the melt;
an image processor that processes an image captured by the first camera to obtain a gap value between a lower end of the heat shielding body and a melt surface; and
a controller that controls a level of the liquid surface of the melt based on a processing result of the captured image by the image processor,
wherein the image processor
sets, while capturing the image, a detection line extending in an oblique direction that is neither parallel nor perpendicular to a pulling-up axis of the single crystal and intersects both a real image edge and a mirror image edge of the heat shielding body; and
finds a gap value, which is a distance between a lower end of the heat shielding body and the melt surface based on a distance on the detection line between the real image and the mirror image, which is a distance from a first intersection point of the detection line and the real image edge to a second intersection point of the detection line and the mirror image.

7. The single crystal manufacturing device according to claim 6, wherein an optical axis of the first camera is in a twisted positional relationship, not in the same plane as a pulling-up axis of the single crystal.

8. The single crystal manufacturing device according to claim 6, further comprising: a second camera that captures a real image of the heat shielding body and a mirror image of the heat shielding body reflected on a liquid surface of the melt,
wherein the image processor measures a diameter of the single crystal using the imaged captured by the second camera.

9. The single crystal manufacturing device according to claim 6, wherein the image processor prepares in advance a conversion table or a conversion formula indicating a relationship between a distance on the detection line between the real image and the mirror image and the gap value when the liquid surface level of the melt is arbitrarily changed by lifting and lowering the crucible before starting pulling up the crystal, and calculates the gap value using the actually measured real image-mirror image distance, and conversion table or conversion formula during the crystal pulling-up step.

10. The single crystal manufacturing device according to claim 9, further comprising:
a measuring pin arranged above the melt, and
the image processor obtains a standard liquid surface level by observing a contact between a tip of the measuring pin and the melt surface, and prepares the conversion table or the conversion formula based on the standard liquid surface level.
